(19) United States
(12) Patent Application Publication
(10) Pub. No.: US 2025/0379104 A1
(43) Pub. Date: Dec. 11, 2025

(54) WAFER CENTER MONITOR

(71) Applicant: TEXAS INSTRUMENTS INCORPORATED, Dallas, TX (US)

(72) Inventors: Rui Ma, Chengdu (CN); Chao Zuo, Chengdu (CN); Rui Liu, Chengdu (CN); Yufeng Peng, Chendgu (CN); Qing Song Ran, Zunyi (CN); Shu Min Ma, Chengdu (CN); Qiming Tao, Chengdu (CN); Lei Zhang, Chengdu (CN)

(21) Appl. No.: 18/752,968

(22) Filed: Jun. 25, 2024

(30) Foreign Application Priority Data
Jun. 7, 2024 (CN) 202410741005.3

(51) Int. Cl. H01L 21/66; H01L 21/67; H01L 23/544

(52) U.S. Cl. CPC H01L 22/12; H01L 21/67288; H01L 23/544; H01L 2223/54426

(57) ABSTRACT

A wafer center monitoring system associated with a semiconductor processing tool. In one example, the semiconductor processing tool may include a wafer stage and an imaging system configured to determine a spatial relationship between a processed area of a semiconductor wafer on the wafer stage and a plurality of fiducial markers placed at a corresponding plurality of locations along a perimeter of the semiconductor wafer.

### FIELD OF THE DISCLOSURE

Disclosed implementations relate generally to the field of integrated circuits (ICs) and IC fabrication.

### BACKGROUND

Within the semiconductor industry, there is a constant demand for integrated circuits (ICs) that exhibit higher performance at a lower cost. In order to design and manufacture high performance ICs cost-effectively, several parameters of the products flowing through a manufacturing process, e.g., process wafers, need to be monitored and carefully controlled. For example, film properties, thicknesses, linewidths, etch profiles, etc., need to be measured, first to optimize the manufacturing process, and then subsequently to ensure that various process stages as well as associated equipment are operating under control.

### SUMMARY

The following presents a simplified summary in order to provide a basic understanding of some examples of the present disclosure. This summary is not an extensive overview of the examples, and is neither intended to identify key or critical elements of the examples, nor to delineate the scope thereof. Rather, the primary purpose of the summary is to present some concepts of the present disclosure in a simplified form as a prelude to a more detailed description that is presented in subsequent sections further below.

Examples of the present disclosure are directed to wafer center monitoring in an IC fabrication flow. In one arrangement, a semiconductor processing tool may comprise a wafer stage; and an imaging system configured to determine a spatial relationship between a processed area of a semiconductor wafer on the wafer stage and a plurality of fiducial markers placed at a corresponding plurality of locations along a perimeter of the semiconductor wafer.

In one example, a method of manufacturing an IC may comprise forming a plurality of fiducial markers over a semiconductor substrate, the fiducial markers placed at a perimeter of the semiconductor substrate at a corresponding plurality of locations; and forming a plurality of instances of the IC on or over the semiconductor substrate.

In one example, a semiconductor wafer may comprise a semiconductor substrate; a plurality of instances of the IC on or over the semiconductor substrate; and a plurality of fiducial markers over the semiconductor substrate, the fiducial markers placed at a perimeter of the semiconductor substrate at a corresponding plurality of locations.

### BRIEF DESCRIPTION OF THE DRAWINGS

Implementations of the present disclosure are illustrated by way of example, and not by way of limitation, in the Figures of the accompanying drawings. Different references to “an” or “one” implementation in this disclosure are not necessarily to the same implementation, and such references may mean at least one. Further, when a particular feature, structure, or characteristic is described in connection with an implementation, such feature, structure, or characteristic in connection with other implementations may be feasible whether or not explicitly described.

The accompanying drawings are incorporated into and form a part of the specification to illustrate one or more example implementations of the present disclosure. Various advantages and features of the disclosure described in the following Detailed Description taken in connection with the appended claims and with reference to the attached drawing Figures in which:

FIG. 1 depicts a representative metrology system that may be deployed in association with one or more process stages of a wafer fabrication flow for monitoring wafer centering or leveling relative to a wafer edge cover ring according to some examples of the present disclosure;

FIG. 2 depicts a general schematic representation of a wafer processing tool configured to monitor wafer centering or leveling relative to a wafer edge cover ring according to some examples of the present disclosure;

FIG. 3A depicts an example scenario of a wafer edge cover ring deployed in relation to a semiconductor wafer with little or no tilt at a process stage in some implementations;

FIG. 3B depicts an example scenario of tilting of a wafer edge cover ring that may cause a non-concentric processed area over a semiconductor wafer at a process stage in some implementations;

FIGS. 4A-4D depict example fiducial markers that may be placed on semiconductor wafers for monitoring concentricity of a processed area relative to a circular semiconductor wafer according to some implementations;

FIG. 5A depicts an example semiconductor wafer having four calibrated fiducial markers at respective cardinal points proximate to a periphery of the semiconductor wafer for facilitating level monitoring according to some implementations;

FIG. 5B depicts a detail of a calibrated fiducial marker shown in FIG. 5A;

FIG. 6 depicts an example scenario where a concentric processed area over a semiconductor wafer is caused by a wafer edge cover ring without a tilt;

FIG. 7A depicts an example scenario where a non-concentric processed area over a semiconductor wafer is caused by a wafer edge cover ring having a tilt;

FIG. 7B depicts a detail of a peripheral dot matrix marker traversed by a perimeter of the non-concentric processed area shown in FIG. 7A;

FIG. 8 depicts a calibration flow for characterizing a ring-to-wafer level alignment monitoring system based on processing of one or more semiconductor wafers;

FIGS. 9-11 depict flowcharts of example fabrication methods according to some implementations; and

FIG. 12 depicts an example rectilinear coordinate system relative to a crystal orientation of a semiconductor wafer that may be used for placement of a plurality of fiducial markers according to some examples.

### DETAILED DESCRIPTION

Examples of the disclosure are described with reference to the attached Figures where like reference numerals are generally utilized to refer to like elements. The Figures are not drawn to scale and they are provided merely to illustrate examples. Numerous specific details, relationships, and methods are set forth below to provide an understanding of one or more examples. However, some examples may be practiced without such specific details. In other instances, well-known subsystems, components, structures and techniques have not been shown in detail in order not to obscure the understanding of the examples. Accordingly, the examples of the present disclosure may be practiced without such specific components.

Additionally, terms such as “coupled” and “connected,” along with their derivatives, may be used in the following description, claims, or both. It should be understood that these terms are not necessarily intended as synonyms for each other. “Coupled” may be used to indicate that two or more elements, which may or may not be in direct physical or electrical contact with each other, co-operate or interact with each other. “Connected” may be used to indicate the establishment of communication, i.e., a communicative relationship, between two or more elements that are coupled with each other. Further, in one or more examples set forth herein, generally speaking, an element, component or module may be configured to perform a function if the element may be programmed for performing or otherwise structurally arranged to perform that function.

Without limitation, examples of the present disclosure will be set forth below in the context of a semiconductor fabrication flow where equipment deployed at a process stage may include a wafer edge cover ring for processing semiconductor wafers.

Depending on implementation, a semiconductor manufacturing process may comprise a fabrication flow involving one or more thin-film and/or thick-film processing/deposition stages, one or more photolithography stages, implant stages, etching stages, chemical-mechanical polishing (CMP) stages, metallization stages, etc., among others, where semiconductor wafers (also referred to as “semiconductor process wafers”) may be processed on a wafer-by-wafer basis, on a lot-by-lot basis, or in a batch mode involving a number of wafer lots or process runs. At an example process stage, a material layer of the semiconductor wafer may be processed so as to alter one or more physical and/or electrical characteristics of the material layer. In some examples, a process stage may add to or subtract from a material layer, e.g., deposition of conductive layers, nonconductive or dielectric layers, etching of features with various aspect ratios, polishing of layers, and/or the like. In an example flow, one or more process steps or stages may be selected, monitored, or otherwise targeted for quality inspection involving appropriate instrumentation, where one or more parameters relating to a material layer may be measured in order to determine, verify and/or ensure quality at the targeted process stage as well as proper functioning of the equipment.

Whereas a primary goal of wafer processing remains obtaining the largest useful surface area, and as a result the greatest number of functional chips possible from each wafer, processing near the circular peripheral edge of a semiconductor wafer is known to give rise to several quality concerns, such as peeling or flaking of particulate matter near edges, lack of uniformity/thickness of deposited or polished layers, uneven etch profiles, and the like, to name a few. These issues may be further exacerbated where wafers with beveled edges are used in fabrication. Wafer edge cover rings (also referred to as “shadow rings”) are often used in association with wafers at various process stages to address the foregoing concerns by creating annular process exclusion areas along the peripheral edge of the circular wafers where the intended process may be avoided. Examples of processing equipment that employ edge cover rings include, e.g., chemical vapor deposition (CVD) tools, physical vapor deposition (PVD) tools, plasma enhanced CVD (PECVD) tools, trench etch tools, etc.

Although the use of edge cover rings in fabrication equipment can be advantageous, lack of proper alignment and/or centering with respect to wafers may create another set of issues, however. Where the edge cover ring is properly aligned and leveled with a semiconductor wafer disposed in a process chamber, a circular processed area is formed over the wafer that is circumscribed by a uniform annular process exclusion area extending between the wafer periphery and the periphery of the processed area, which is indicative of uniformity of the intended process (e.g., deposition, etch, polishing, etc.). On the other hand, if the edge cover ring is not leveled with respect to the semiconductor wafer, e.g., tilted relative to the wafer, the edge cover ring may not mask or shield the edge of the wafer uniformly, thus causing uneven films or etch profiles to be over the wafer, which can potentially impact die yield.

Examples of the present disclosure recognize the foregoing challenges and advantageously provide a level monitoring scheme where semiconductor process wafers may be provided with a plurality of calibrated fiducial markers proximate to the wafer peripheral edge, which may be configured to facilitate measurements of non-uniformity of process exclusion areas caused by ring-to-wafer misalignment and/or tilting. Because non-concentricity of the circular processed areas relative to the circular wafers is related to the non-uniform annular distance of process exclusion areas, some examples may be configured to obtain a measurement of non-concentricity in terms of a deviation of the processed area along the orthogonal axes of a horizontal plane associated with the wafer. In some examples, the measurements of non-uniformity, non-concentricity, etc., may be applied in suitable statistical process control (SPC) or statistical quality control (SQC) methodologies deployed in a fabrication facility in order to monitor and control a process flow at various stages. In some arrangements, example SPC/SQC methodologies may be deployed at a targeted process stage considered to be a critical process stage so as to help ensure that the targeted process stage is operating efficiently and within control, thereby producing more conforming products with less waste (e.g., rework, scrap or other disposition). For example, process wafers, wafer lots, and/or process runs may be monitored to confirm that applicable control limits and/or specification thresholds are satisfied with respect to ring-to-wafer alignment as well as measurement parameters and/or variables relevant to the material layer(s) being processed at the targeted process stage. Whereas examples of the present disclosure may provide techniques and processes that may be configured to facilitate yield enhancement in a fabrication line, no particular result is a requirement unless explicitly recited in a particular claim.

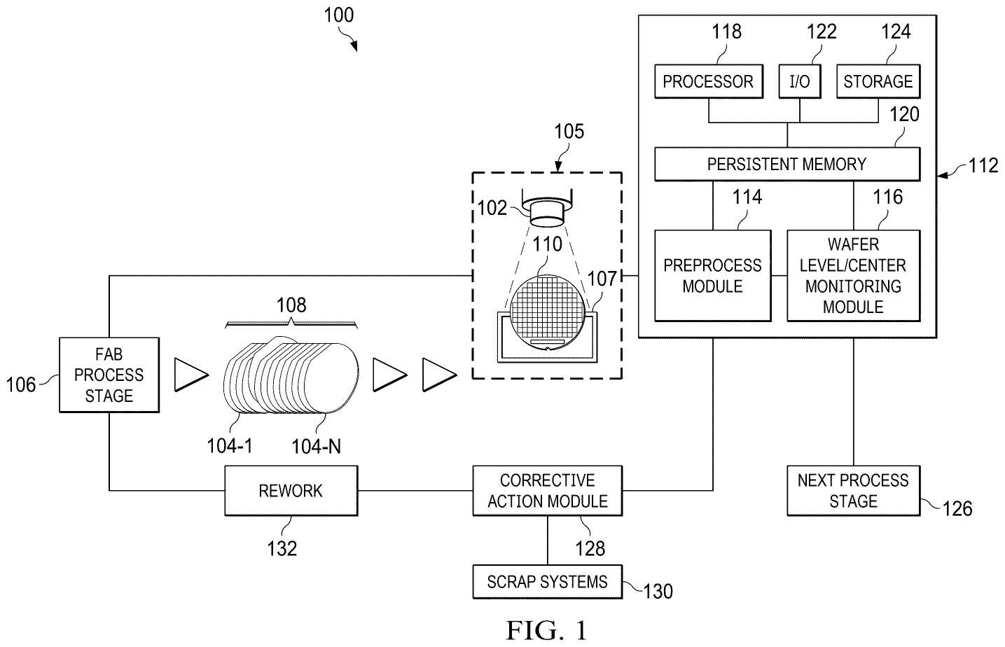

Referring to the drawings, FIG. 1 depicts a representative metrology system 100 that may be implemented in association with one or more process stages of a wafer fabrication flow for monitoring wafer centering or leveling relative to a wafer edge cover ring according to some examples of the present disclosure. Because the alignment and/or leveling between a wafer and the edge cover ring may be measured relative to each other, the illustrated metrology system 100 may be configured as a wafer level monitoring system, a wafer center monitoring system, an edge cover ring level monitoring system, a ring-to-wafer alignment monitoring system, and the like, where the example systems are roughly analogous to one another. As will be set forth further below, regardless of the particular nomenclature used for describing an example monitoring system, an implementation of the system may include both hardware and software components configured to operate with a processing tool including a wafer edge cover ring deployed at a process stage, or with a separate inspection tool used after the process stage. Further, the hardware and software components of an example system may be configured to determine, calculate, or otherwise obtain ring-to-wafer alignment/leveling of the processing tool based on measurements associated with processed areas formed on the circular wafers, where a set of calibrated fiducial markers are provided with the wafers as part of a marking process for facilitating manual and/or automated measurements.

A generalized process stage 106 is illustrated in FIG. 1 that may represent a particular process stage of an example fabrication flow where a processing tool including a wafer edge cover ring is deployed (not shown in this Figure) for processing of wafers, e.g., wafers 104-1 to 104-N. Depending on the process stage and tool configuration, the wafers 104-1 to 104-N may be processed on a wafer-by-wafer basis or in a batch mode, e.g., as a wafer lot 108, where the individual wafers may have one or more flats, notches, and the like, for facilitating safe handling and alignment in fabrication equipment as well as identifying the type and crystallographic orientation of the wafers. Depending on implementation, flats may be provided as straight edges cut into one or more sides of a round wafer, and may comprise primary and secondary flats where multiple flats are provided. Notches may comprise V-shaped or U-shaped indentations provided in the perimeter of the wafer. In general, flat/notch sizes and locations may depend on the wafer dimensions, which may be specified according to industry standards, e.g., Semiconductor Equipment and Materials International (SEMI) standards.

Further, the wafers 104-1 to 104-N may have unique identification marks or patterns, including alphanumeric sequences, engraved on or otherwise applied to the bare or oxidized wafer surface, generally proximate to the flat or notch, at the beginning of the flow in order to facilitate tracking, product identification, production quality control, process management, etc. As will be set forth further below, additional marks may be provided at the peripheral edge of the wafers during the initial marking stage, where the additional marks may comprise calibrated indicia that may be inspected, measured, or otherwise analyzed for determining the non-concentricity of a processed area relative to the circular wafer on which the processed area is formed at a targeted process stage, e.g., the process stage 106.

In some examples, fabrication equipment 105 associated with the process stage 106 may include a wafer stage 107 for supporting a semiconductor substrate, e.g., a process wafer 110. In some examples, an image capturing system 102, e.g., a camera or an image sensor, may be associated with the fabrication equipment 105 for inspecting the wafer 110 after processing. In one example arrangement, the camera or image sensor 102 may be configured to generate an image of an entire wafer in its field of view, where the coverage of a processed area over relative to the calibrated indicia markers (also referred to as fiducial markers) of the wafer 110 may be inspected and analyzed. In some arrangements, a computing platform 112 associated with the fabrication equipment 105 may be configured to operate as a data acquisition and processing system operable with the image sensor 102 for facilitating data acquisition, image processing and wafer level monitoring under suitable programmatic control according to some examples herein. Depending on implementation, the computing platform 112 may be integrated with the fabrication equipment 105 of the process stage 106, e.g., in a cluster tool configuration, or deployed as a standalone or a networked workstation at a centralized location of a fabrication facility. In an example arrangement, the computing platform 112 may include one or more processors 118 coupled to a persistent memory 120 containing machine-executable code or program instructions, where an (optional) image preprocessing module 114 and a wafer level/center monitoring module 116 may be provided for execution by processor(s) 118 under programmatic control in order to perform wafer image processing and determine or measure deviations of annular process exclusion areas from suitable thresholds, which may result from ring-to-wafer level shift/misalignment in the fabrication equipment.

In some arrangements, the image capturing system 102 and the computing platform 112 may be co-located or otherwise integrated to operate as an imaging system for purposes of some examples. In some arrangements, the imaging system may be configured to obtain spatial relationships between processed areas and the fiducial markers formed on the wafers. In some arrangements, the imaging system may be coupled to an in-line metrological station (not shown in this Figure) to measure parameters such as film thickness, sheet resistance, etch profiles, and the like, in order to obtain functional relationships between ring-to-wafer level shift/misalignment and the measured parameters. In some arrangements, a determination may be made in association with a corrective action module 128, which may be facilitated by human experts and/or expert systems based on artificial intelligence (AI), as to whether any wafers deemed to be out-of-specification may be reworked in a cost-effective manner or not. In some arrangements, any wafers determined to be reworkable may be provided to a rework system 132 (e.g., via a robot handler, not shown in this FIG.) for transferring such wafers back into the flow, e.g., the targeted fabrication process stage 106 where the parametric anomalies are predicted to have been caused. In some arrangements, a determination may be made whether the process exclusion areas are within an acceptable range such that the wafers may be transferred to a next processing stage 126. Further, a wafer scrap system 130 may be provided for handling the wafers determined to be non-reworkable, e.g., not in a cost-effective manner.

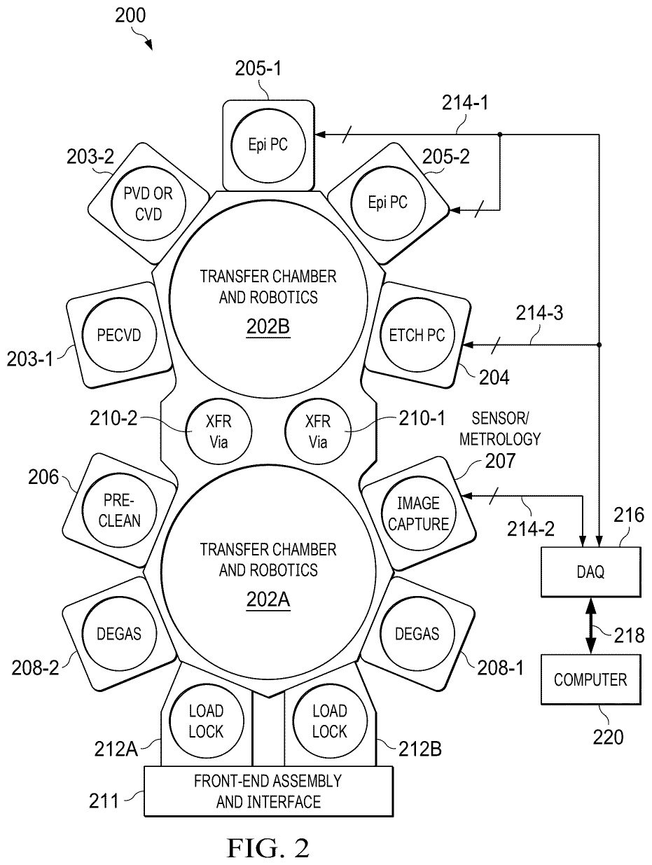

FIG. 2 depicts a general schematic representation of a wafer processing system or tool 200 that may be deployed in association with one or more process stages of a wafer fabrication flow and configured to monitor wafer centering or leveling relative to a wafer edge cover ring according to some examples of the present disclosure. In some arrangements, the processing tool 200 may be configured as a multifunctional tooling system, e.g., a cluster tool system, that allows for the automatic transfer of semiconductor process wafers between different reactor chambers or process chambers configured to effectuate different processes, or to process similar layers in parallel, without exposing the wafers to external environment in between the process steps. In an example arrangement, accordingly, one or more process chambers may be provided that are operable as respective working volumes, each adapted to effectuate corresponding process steps, operations and/or recipes associated with a broad range of wafer fabrication flows including but not limited to deposition, etching, polishing, thermal processing/annealing, etc., as well as operations such pre-/post-clean processes, degas operations, surface conditioning operations, and the like. By way of illustration, the tool system 200 may include deposition chambers 203-1, 203-2, etch chambers 204, epitaxy process chambers 205-1, 205-2, pre-clean chamber(s) 206 (e.g., using RF or plasma), and degas chambers 208-1, 208-2, in an example arrangement. Further, one or more sense chambers 207 may be provided as part of the tool system 200 where the processed wafers may undergo appropriate sensing, image capture and/or other metrological operations.

In some arrangements, the processing tool 200 may be configured to include multiple main chambers 202A, 202B to which the foregoing process chambers and sensing/metrology chambers may be detachably coupled. In one arrangement, a first main chamber, e.g., main chamber 202A, may be configured as a buffer chamber having robotic wafer handling capability for facilitating loading and/or unloading of semiconductor process wafers using load lock chambers 212A and 212B coupled to a front-end assembly and interface 211 that is adapted to cooperate with specialized wafer carrier systems, e.g., Front Opening Unified Pods (FOUPs), Front Opening Shipping Boxes (FOSBs), etc. Main chamber 202A may also operate as a transfer chamber for facilitating the transfer for process wafers between different process chambers coupled thereto. Likewise, a second main chamber, e.g., main chamber 202B, may also be configured as a transfer chamber that may also include a robotic wafer handling system for facilitating the transfer of wafers from one process chamber to another depending on the process flow. In some examples, robotic wafer handling systems may comprise a robotic arm operative to rotate around vertical and horizontal axes as well as travel on any plane in a 3D space enclosed by main chambers 202A, 202B. One or more transfer vias or conduits 210-1, 210-2 may be coupled between the main chambers 202A and 202B for facilitating the transfer for process wafers between the two main chambers 202A and 202B. In some arrangements, appropriate cooling chambers may be provided (not specifically shown in this Figure) for cooling/regulating the temperatures of the process wafers prior to or after a processing stage.

Depending on implementation and/or process flow requirements, various processing chambers, load lock chambers, sensor/metrology chamber(s), any additional/expansion chambers, as well as main chambers 202A, 202B may be (de)pressurized to varying levels using appropriate gases (e.g., Argon, Nitrogen, etc.) in conjunction with one or more servomechanical vacuum pumps and associated hardware (e.g., cryo pumps, turbo pumps, rotary vane pumps, etc., not specifically shown in this Figure). Suitable mechanical coupling between main chamber 202A, 202B and other chambers may therefore be provided in order to facilitate chamber detachability while maintaining vacuum integrity during operation.

In one arrangement, suitable communication interfaces may be provided with various process chambers as well as sensor/metrology chambers, which may be coupled to a data acquisition (DAQ) unit 216 for collecting sensor data, image data, etc., and transmitting the data to a host computer 220 using any known or heretofore unknown data collection/transmission protocols via a local network and/or a remote network 218. By way of example, interfaces 214-1, 214-2 and 214-3 are illustrated in this Figure. In addition to data gathering, monitoring and processing, the host computer 220 may be configured to execute appropriate process software or programs for effectuating and/or controlling various process recipes, and the like. In some arrangements, the host computer 220 may be configured as a computing platform, e.g., the platform 112 shown in FIG. 1, operable to effectuate ring-to-wafer alignment monitoring with respect to one or more process chambers of the tool system 200 that may include wafer edge cover rings in respective chambers. Depending on implementation, the host computer 220 may be deployed as a local or remote host, or at a cloud-based data center associated with an IC fabrication facility, which may include one or more processors operating under program control to effectuate sensing processes and process recipes, data analysis, report generation, etc.

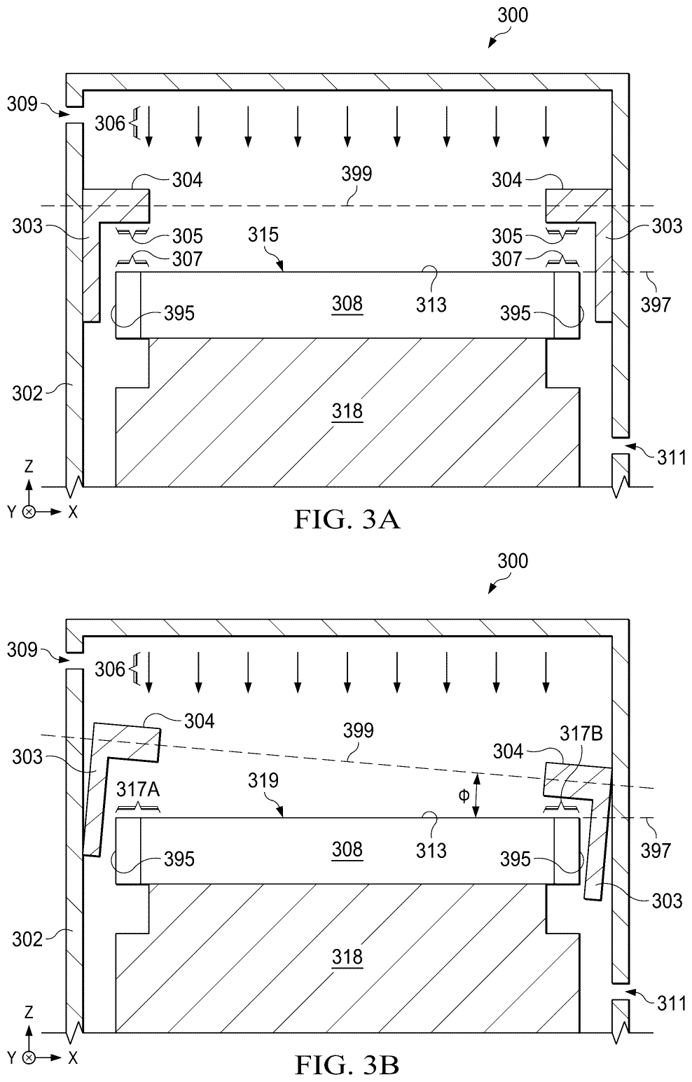

FIG. 3A depicts an example scenario of a wafer edge cover ring deployed in relation to a semiconductor wafer with little or no tilt at a process stage in some implementations. FIG. 3B depicts an example scenario of tilting of a wafer edge cover ring that may cause a non-concentric processed area over a semiconductor wafer resulting in a non-uniform annular process exclusion area in some implementations. Taking FIGS. 3A and 3B together, set forth below is a generalized fabrication scenario representative of a process stage such as the process stage 106 described above. Without limitation, a process chamber 300 having a housing or body 302 is representative of a deposition chamber, an etch chamber, etc., where suitable ingress ports 309 and egress ports 311 may be provided for facilitating the transport of suitable reactants, precursors, etc., into the housing 302 and the transport of byproducts out of the housing 302, respectively. Input reactants/precursors may be provided via one or more perforated applicators, informally referred to as “showerheads” (not shown in FIGS. 3A and 3B) coupled to the ingress port(s) 309. Depending on processing recipes, input reactants/precursors may undergo chemical reactions and/or may be energized (e.g., using RF sources, not shown in FIGS. 3A and 3B) to create reactive species 306 (e.g., plasma) that may be applied to a semiconductor substrate, e.g., a process wafer 308, disposed over a wafer support stage or platform 318 (also referred to as a chuck).

A shadow ring or edge cover ring 303, shown in a cross-sectional view herein, is disposed inside the chamber housing 302 and above the wafer support platform 318. In some arrangements, the edge cover ring 303 may be supported by a chamber body ring (not shown in FIGS. 3A and 3B) coupled to an internal surface of the housing 302. The wafer support platform 318 may be made of a material resistant to chemical processing, such as aluminum and/or ceramic, and may include a heating element in some arrangements (not shown in FIGS. 3A and 3B). In one example arrangement, the edge cover ring 303 may comprise an annular flange 304 having a width 305 dimensioned to mask or shield a circular edge 395 of the semiconductor wafer 308 by a preconfigured width depending on the process stage. Accordingly, an annular process exclusion area having a width 307 may be formed over a top surface 313 of the semiconductor wafer 308.

In operation, the wafer support platform 318 is initially lowered to a wafer transfer position (not shown in FIGS. 3A and 3B) within the housing 302. A wafer handler comprising a robot blade (not shown) may be configured to carry a wafer, e.g., wafer 308, into position above the wafer support platform 318. A plurality of lift pins (not shown) may be configured to lift the wafer 308 off the robot blade, whereupon the robot blade may retract from the chamber 300. The wafer support platform 318 may thereafter be elevated to position the wafer 308 thereon at a particular horizontal location within the housing 302 in relation to the edge cover ring 303. After the semiconductor wafer 308 is in the processing position, precursor gases may be provided to the chamber housing 302 for effectuating the intended processing step.

Where the edge cover ring 303 is properly aligned and centered over the semiconductor wafer 308, it is expected that there will be little or no angular deviation between a plane 399 through the flange 304 and a horizontal plane 397 of the semiconductor wafer 308. Accordingly, the flange 304 symmetrically covers the peripheral edge 395 of the semiconductor wafer 308 during the application of precursor gases, thereby forming a uniform process exclusion area (e.g., having the width 307) around a circular processed area 315. On the other hand, if there is an angular deviation (e.g., ϕ°) between the flange plane 399 of the edge cover ring 303 and the horizontal plane 397 of the semiconductor wafer 308 as illustrated in FIG. 3B, the flange 304 may cover the peripheral edge 395 of the semiconductor wafer 308 asymmetrically, thereby causing the circular processed area 319 to be off-center (i.e., non-concentric) relative to the circular semiconductor wafer 308. Accordingly, a non-uniform process exclusion area 317A, 317B surrounding the circular processed area 319 may be formed over the semiconductor wafer 308.

Relative tilting and/or misalignment between the edge cover ring 303 and the semiconductor wafer 308 may occur due to rotational shift of a corresponding plane around one or more axes of the three-dimensional space enclosed in the housing 302. For purposes of the present disclosure, the term “level shifting” may include rotational shifting of the edge cover ring 303 around the X-axis, the Y-axis or around an axis coplanar with an X-Y-plane depending on the examples unless otherwise stated or implied from the associated description. Accordingly, level shifting or relative tilting between a wafer and the edge cover ring of a process tool may comprise an angular deviation between a horizontal plane of the wafer and a horizontal plane of the edge cover ring. In an example tool environment, such deviations may be caused due to mechanical shifting of the edge cover ring produced by thermal-mechanical stress encountered in the reactor chamber, process drift in the settings of mechanical components of the reactor chamber fixtures including edge cover rings, chamber body rings, etc. Although the horizontal nature of a wafer support platform (and thus the wafer disposed thereon) is generally expected to be stable, e.g., not affected by process drift, etc., if there is any deviation in the setting of a wafer support platform contributing to the relative angular deviation between the wafer support platform and an edge cover ring, such deviations may also be monitored and characterized using a fiducial marking scheme according to some examples herein. This is so because the monitoring methodology based on the measurements of calibrated markers with respect to non-uniform process exclusion areas formed on wafers is agnostic as to the causation of such non-uniform process exclusion areas.

A variety of fiducial markers may be placed on semiconductor wafers for monitoring concentricity, or conversely, non-concentricity, of a processed area relative to a circular semiconductor wafer according to the examples herein. In some arrangements, example fiducial marking schemes may include marking semiconductor wafers at an early stage of fabrication, e.g., before a targeted process stage such as the process stage 106 described above. A sequence of calibrated indicia having a predetermined spatial relationship with one another may be provided as fiducial markers engraved or otherwise formed on a top surface of the wafer substrate on which microelectronic devices, integrated circuits, etc., are formed. In some arrangements, fiducial marking may be performed concurrently with laser scribe marking of wafers for identification and tracking purposes, e.g., using alphanumeric sequences already available for laser ID marking, which may be more cost effective as the need for additional tooling may be obviated.

In general, one or more calibrated fiducial markers may be placed at a corresponding plurality of locations along a perimeter of the wafer. In some example arrangements, the fiducial markers may be provided proximate to the peripheral edge of the wafer, e.g., spaced from the peripheral edge by a same distance. In some example arrangements, a fiducial marker may comprise at least one row or sequence of a plurality of indicia, which is offset from the wafer edge by a distance, where the sequence has a sufficient number of indicia that are spaced according to a desired resolution of measurements. Further, the row or sequence may have a total length (given as (N−1) multiplied by the space between two adjacent indicia, where N=the number of indicia) that is long enough that the periphery of a circular processed area at a targeted process stage is expected to transect the row of indicia for all corner cases of level shifting. Given the distance between the wafer edge and the first indicium of the marker, if the periphery of a circular processed area crosses the marker at a particular indicium, an annular distance between the periphery of the circular processed area and the periphery of the wafer may be calculated. By determining such annular distance at different locations along the wafer edge and comparing the annular distances, a determination may be obtained as to the uniformity of the annular distances. If they are essentially the same, e.g., within ±2%, the annular distance may be characterized as uniform. Accordingly, in such a scenario, the annular process exclusion area may be determined as being uniform, indicating a lack of relative tilting between the wafer and the edge cover ring.

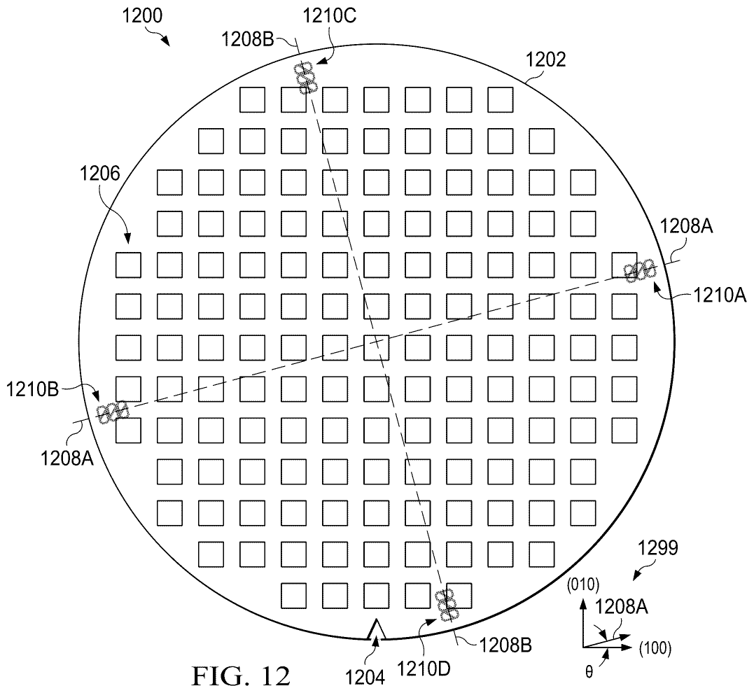

According to some examples herein, at least two calibrated fiducial markers may be provided along the peripheral edge of the wafers at two respective locations that are sufficiently apart from each other so that a tilt between the wafer and an edge cover ring of the process tool can be discriminated. Because of the circular symmetry of wafers, the maximum angular separation between any two fiducial markers is 180°. Accordingly, two calibrated fiducial markers (e.g., a first pair of markers) placed diametrically opposite to each other may be calibrated to provide maximum discrimination in assessing a tilt around an axis (e.g., a first axis) that is orthogonal to the diametrical line extending between the diametrically opposite fiducial markers. In similar manner, another pair of two calibrated fiducial markers (e.g., a second pair of markers) may also be placed diametrically opposite to each other and at a perpendicular angle relative to the first pair of diametrically opposite fiducial markers for discriminating a tilt around a second axis that is orthogonal to the diametrical line extending between the second pair of markers. Accordingly, some examples herein may be configured to provide appropriate fiducial markers at four rectilinear cardinal points of wafers along the perimeter of a wafer, which may be calibrated to facilitate tilt monitoring with 2-degrees of freedom as will be set forth in detail further below.

Whereas a plurality of fiducial markers may be placed at various locations around the wafer edge, they are not placed at or along the special edges and features such as flats and/or notches in some examples because of non-circularity of the wafer periphery in these regions. Some examples herein may therefore be configured to form fiducial markers at corresponding locations along the wafer periphery while avoiding the special wafer locations specified by appropriate SEMI standards. Because notches, flats, etc., of a wafer are indicative of a crystal orientation of the semiconductor substrate, the placement of markers may be defined relative to the crystal orientation of the substrate in some examples. Turning to FIG. 12, a wafer 1200 with a circular periphery or perimeter 1202 and a notch 1204 is shown where a plurality of instances of an IC 1206 are illustrated. A rectilinear coordinate system defined by a first axis 1208A (e.g., an X′ axis) and a second axis 1208B (e.g., a Y′ axis) orthogonal to the first axis 1208A may be used for placing four fiducial markers 1210A-1210D at the corresponding cardinal points ({−X′,0}; {+X′,0}; {0,−Y′} and {0,+Y′}) along the periphery 1202 of the wafer 1200. As the notch 1204 in this example may be indicative of a crystal orientation (e.g., the X-Y plane 1299 corresponding to Miller indices (100) and (010)), the rectilinear coordinate system or space for placing the fiducial markers 1210A-1210D may be rotated by a rotation angle θ as shown in FIG. 12 to avoid the notch location 1204.

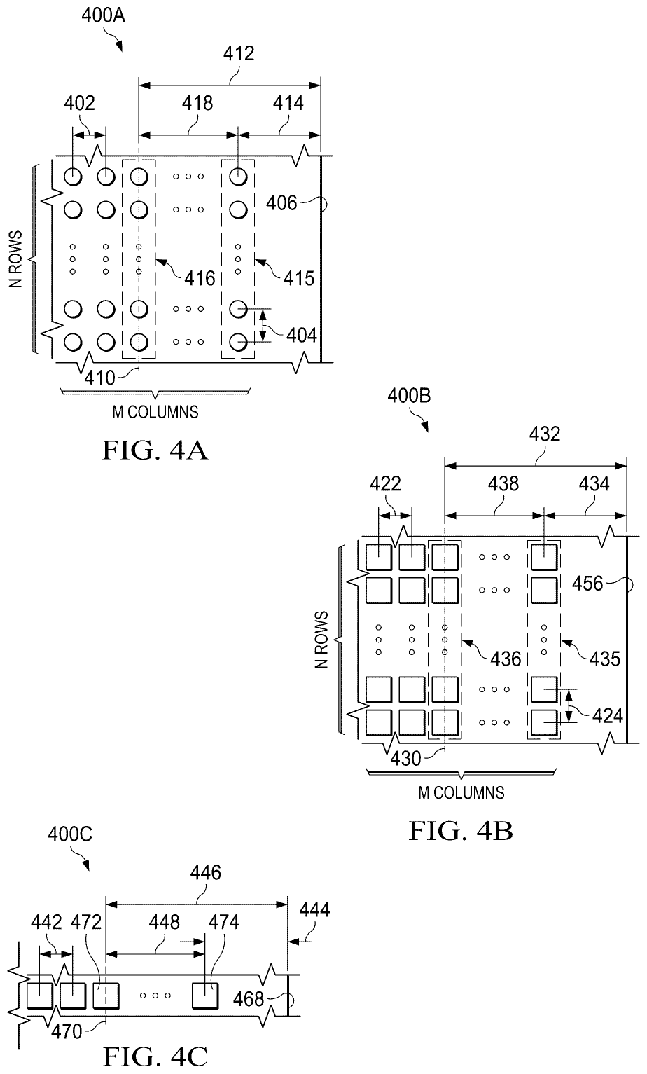

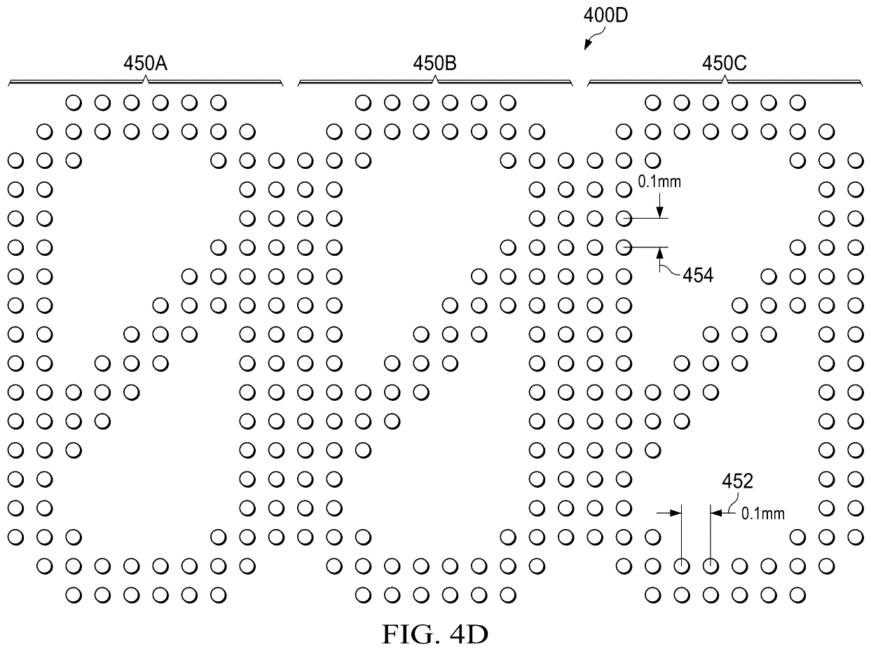

FIGS. 4A-4D depict example fiducial markers according to some examples, where a fiducial marker may be placed on semiconductor wafers in multiple instances at respective peripheral locations. FIG. 4A depicts a fiducial marker 400A comprising an array of indicia, e.g., dots, arranged in a matrix configuration having N rows and M columns, where the N rows are separated by a distance 404 and the M columns are separated by a distance 402. Whereas the distances 402 and 404 may be equal in some implementations, it is not a necessary requirement. The fiducial marker 400A is positioned away from a wafer edge 406, which may be approximated as a straight line or a tangent at the wafer edge location where the marker 405A is placed, by a distance 414. A peripheral edge 410 of a processed area is illustrated as traversing a column 416 of the fiducial marker 400A. A distance 412 between the wafer edge 406 and the peripheral edge 410 of the processed area may therefore be obtained as the distance 414 plus a distance 418 between a first column 415 of the fiducial marker 400A and the traversed column 416 of the fiducial marker 400A.

In similar manner, FIG. 4B depicts an example fiducial marker 400B comprising an array of indicia, e.g., squares, arranged in a matrix configuration having N rows and M columns, where the N rows are separated by a distance 424 and the M columns are separated by a distance 422, which may or may not be equal to the distance 424. The fiducial marker 400B is positioned away from a wafer edge 456, which may be approximated as a straight line or a tangent at the wafer edge location where the marker 400B is placed, by a distance 434. A peripheral edge 430 of a processed area is illustrated as traversing a column 436 of the fiducial marker 400B. A distance 432 between the wafer edge 456 and the peripheral edge 430 of the processed area may therefore be obtained as the distance 434 plus a distance 438 between a first column 435 of the fiducial marker 400B and the traversed column 436 of the fiducial marker 400B.

FIG. 4C depicts a fiducial marker 400C having a single row of indicia, e.g., squares, that are separated by a calibrated distance 442. Similar to the examples set forth above, the fiducial marker 400C is positioned away from a wafer edge 468 by a distance 444. A peripheral edge 470 of a processed area is illustrated as traversing a particular indicium 472 of the fiducial marker 400C. A distance 446 between the wafer edge 468 and the peripheral edge 470 of the processed area may therefore be obtained as the distance 444 plus a distance 448 between a first indicium 475 of the fiducial marker 400C and the traversed indicium 472 of the fiducial marker 400C.

In some arrangements, fiducial marking of wafers may be performed concurrently with laser ID marking of wafers as previously noted. In such arrangements, both fiducial marking and ID marking may be performed using automated laser scribe/marking equipment in batch format. In some arrangements, the laser ID and fiducial markings may be produced in either hard or soft mark configurations. In some arrangements, dot matrix fonts and character sequences may be used to minimize the amount of disruption to the wafer surface. Because little or no material is removed during the lasering process in soft mark configurations, contamination across the wafer area may be reduced in some implementations.

As laser marking equipment and techniques may be readily available in a fabrication facility, similar techniques may also be employed for forming calibrated fiducial markers on wafers or wafer substrates in some examples herein. The non-contact nature of laser marking may reduce the risk of contamination and damage to delicate or pristine silicon wafer surfaces, which is especially critical in advanced process nodes requiring highest quality cleanroom environments. In some implementations, aside from laser engraving, techniques such as annealing and ablation may also be used for marking in additional and/or alternative arrangements.

FIG. 4D depicts an example laser scribe dot matrix (LDM) fiducial marker 400D based on concatenation of three alphanumeric characters, which may form a character sequence or pattern, e.g., a “triple-zero” sequence. As with the example fiducial markers 400A, 400B, and 400C described above, a plurality of fiducial markers 400D may be placed at respective peripheral locations of a wafer while avoiding the notches, flats, etc. As illustrated, a plurality of dots are arranged in the triple-zero sequence marker 400D comprising three individual zero patterns 450A, 450B, 450C, where a first calibrated distance 452, e.g., 0.1 mm, between two adjacent dots along a first direction and a second calibrated distance 454, e.g., 0.1 mm, between two adjacent dots along a second, orthogonal direction may be provided.

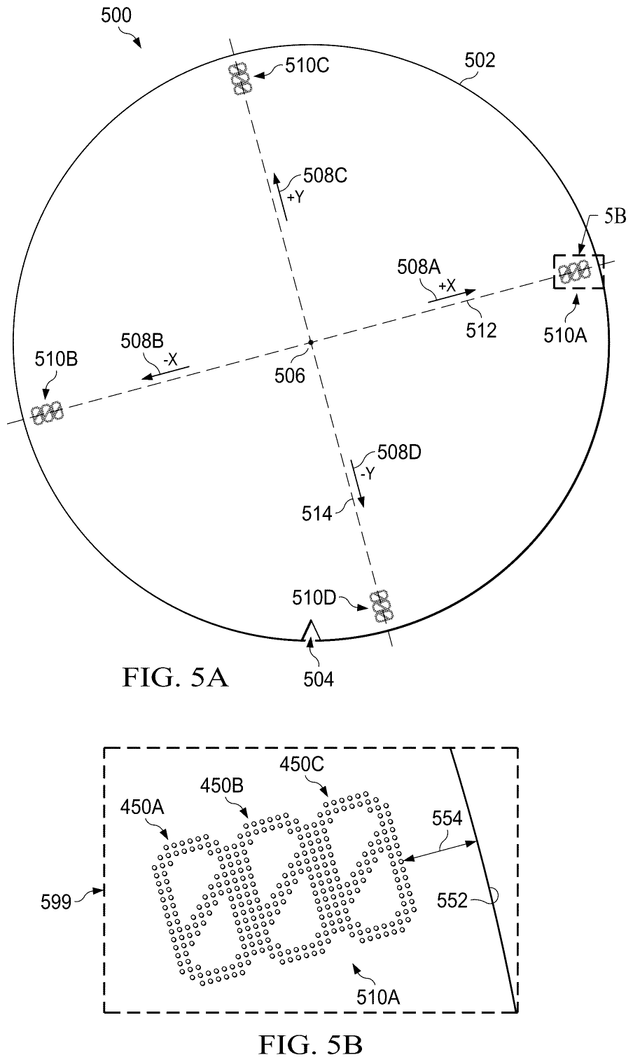

FIG. 5A depicts an example semiconductor wafer 500 having four calibrated fiducial markers comprising LDM triple-zero sequences such as the marker 400D described above. A rectilinear coordinate system defined by four orthogonal radials 508A, 508B, 508C, and 508D extending from a center 506 of the semiconductor wafer 500 may be provided for specifying respective locations for placing four LDM markers 510A, 510B, 510C, and 510D along a peripheral edge 502. As illustrated in this Figure, the rectilinear coordinate system may be rotated by a suitable angular rotation so as to avoid a notch 504, similar to the arrangement shown in FIG. 12 described above. By virtue of the geometrical symmetry of the arrangement, the LDM markers 510A and 510B share a common long axis, e.g., a first axis 512. Likewise, the LDM markers 510C and 510D share a common long axis, e.g., a second axis 514, that is orthogonal to the first axis 512, where the long axes are oriented along the respective radials of the rectilinear coordinate system associated with the wafer 500.

Similar to the fiducial marker arrangements set forth above, each LDM marker may be spaced from the peripheral edge 502 of the wafer 500 by a same distance, e.g., distance 554, as shown in FIG. 5B, which depicts a detail 599 illustrating the spatial arrangement of the LDM marker 510A. Although the peripheral edge portion 552 is shown in the detail 599 as a straight line, an actual physical edge portion may be an arcuate section having some curvature. As the examples herein may be configured to measure or monitor deviations of a processed area relative to the circular peripheral edge 502 along the respective long axes of the fiducial markers, level monitoring schemes of the present disclosure are generally agnostic as to the shape of curvatures of the wafer 500 and a processed area (not shown in this Figure) in some implementations.

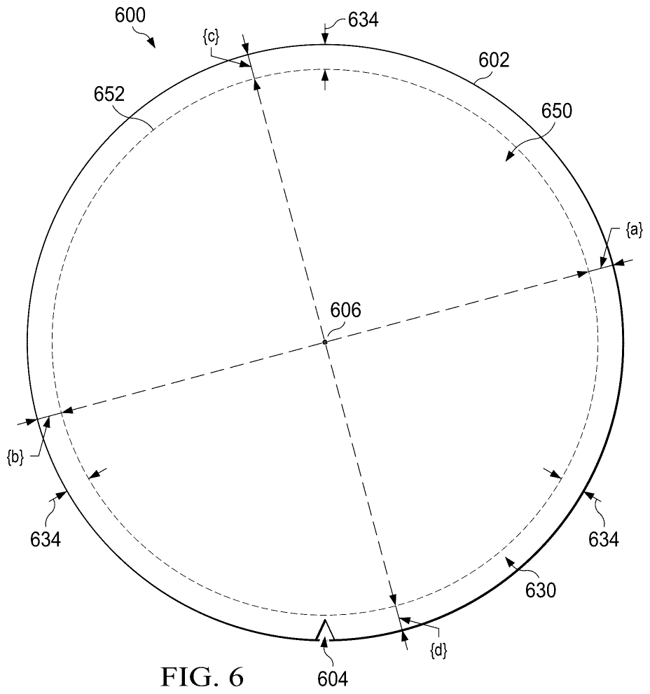

FIG. 6 depicts an example scenario where a processed area 650 having a perimeter 652 is formed over a semiconductor wafer 600 having a perimeter 602 and a notch 604. The processed area 650 is circumscribed by an annular process exclusion area or zone 630 having a uniform width 634, which may be caused by an edge cover ring without a tilt deployed at a targeted process stage. As the processed area 650 and the wafer 600 are concentric, the respective centers coincide at a common center 606, e.g., without an offset between a center of the wafer 600 and a center of the processed area 650.

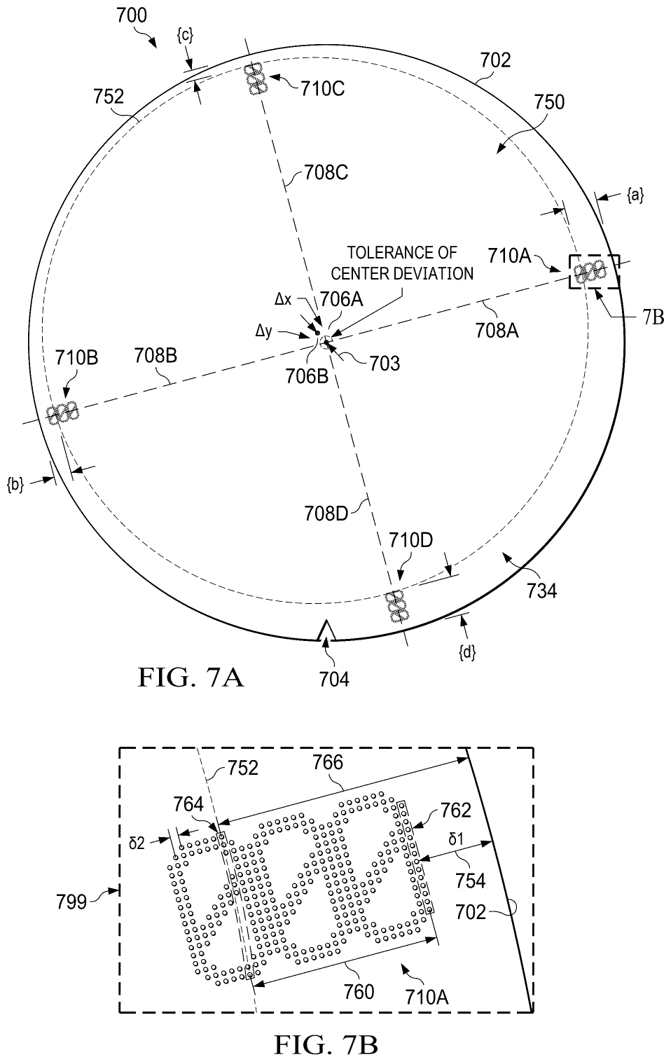

FIG. 7A depicts an example scenario where a non-concentric processed area 750 is formed over a semiconductor wafer 700 having an edge or perimeter 702 and a notch 704 due to relative tilting of an edge cover ring. As illustrated in this scenario, the semiconductor wafer 700 is provided with four LDM fiducial markers 710A, 710B, 710C, and 710D, that are placed proximate to four cardinal points located on the perimeter 702 defined by respective radials 708A, 708B, 708C, and 708D, similar to the arrangement shown in FIG. 5A. Because a perimeter 752 of the processed area 750 is non-concentric with respect to the perimeter 702 of the semiconductor wafer 700, a non-uniform process exclusion area 734 is formed over the semiconductor wafer 700. Accordingly, a center 706B of the processed area 750 is offset from a center 706A of the semiconductor wafer 700 by a radial distance 703, which may be defined in terms of rectilinear coordinates such as ΔX and ΔY, or equivalently, in polar coordinates (ρ, θ) in some additional and/or alternative implementations.

Under conditions of concentricity, a process exclusion area is expected to have a uniform width or distance between the edge of a wafer and the edge of a processed area along a radial extending from the wafer's center. Accordingly, in a rectilinear coordinate system, an annular distance between the edge of the processed area and the edge of the wafer along a first radial (e.g., distance {a} shown in FIG. 6) is identical to and a counterpart of an annular distance (e.g., distance {b} shown in FIG. 6) between the edge of the processed area and the edge of the wafer along a second radial opposite to the first radial (e.g., at 180°). In similar fashion, an annular distance (e.g., distance {c} shown in FIG. 6) between the edge of the processed area and the edge of the wafer along a third radial is identical to and a counterpart of an annular distance (e.g., distance {d} shown in FIG. 6) between the edge of the processed area and the edge of the wafer along a fourth radial opposite to the third radial (e.g., at 180°). Further, due to the symmetrical nature of the rectilinear coordinate system, a deviation in the annular distance {a} is a complementary deviation in the annular distance {b} and a deviation in the annular distance {c} is a complementary deviation in the annular distance {d}. Under these principles, the sum of annular distances along a first axis (e.g., {a}+{b} along the X-axis) is identical to the sum of distances along a second orthogonal axis (e.g., {c}+{d} along the Y-axis). For a given sum of counterpart annular distances, e.g., {a}+{b}={c}+{d}=m, an offset in the center of a non-concentric processed area relative to the center of a semiconductor wafer in a rectilinear coordinate system may be computed as follows:

$$Δ X = \vert a - ( m / 2 ) \vert or \vert b - ( m / 2 ) \vert ; and$$

$$Δ Y = \vert c - ( m / 2 ) \vert or \vert d - ( m / 2 ) \vert .$$

In examples herein, the foregoing X-axis and/or Y-axis deviations may be obtained by using a calibrated fiducial marker whose long axis is oriented along a radial extending from the center of a semiconductor wafer such as, e.g., the semiconductor wafer 700 of FIG. 7A. In some examples, the deviations may be based on measuring, computing or otherwise obtaining a total distance 766 between the processed area perimeter 752 and the wafer edge 702, as illustrated in a detail 799 depicted in FIG. 7B. In this example, the distance 766 may be obtained as a sum of a distance 754 between a first indicium of a calibrated fiducial marker aligned to a corresponding radial (e.g., a first vertical row of dots 762 of the LDM marker 710A nearest to the wafer edge 702) and the wafer edge 702 (e.g., {n} mm), and a distance 760 between the first indicium and a second indicium (e.g., a N^{th} vertical row of dots 764 of the LDM marker 710A) that is traversed by the processed area perimeter 752. Given a predetermined distance between adjacent vertical rows (also referred to as columns) of the LDM marker 710A, the total distance 766 may be obtained as ((N−1)δ₂+δ₁), where δ₁ is the distance 754 and δ₂ is the inter-column distance, e.g., analogous to the distance 452 shown in the example of FIG. 4D.

In some examples, various threshold values and ranges may be established with respect to the linear offsets or deviations, e.g., ΔX and ΔY in a rectilinear coordinate system, and/or center offsets, e.g., Δρ where Δρ=√{(ΔX)²+(ΔY)²)} in a polar coordinate system. In some examples, SPC/SQC specifications may be provided with respect to the deviations and associated thresholds, which may be used for facilitating in-line product disposition, quality control, adjustment(s) with respect to equipment settings (e.g., edge cover ring settings, etc.), as noted previously. In some examples, an image system may be provided as an optical inspection tool configured to determine the foregoing spatial relationships between the processed areas and the wafers, where the image system may be deployed as part of a processing tool at a process stage, as a separate monitoring station (e.g., local or remote), etc., as set forth above reference to the examples of FIGS. 1 and 2, without limitation thereto.

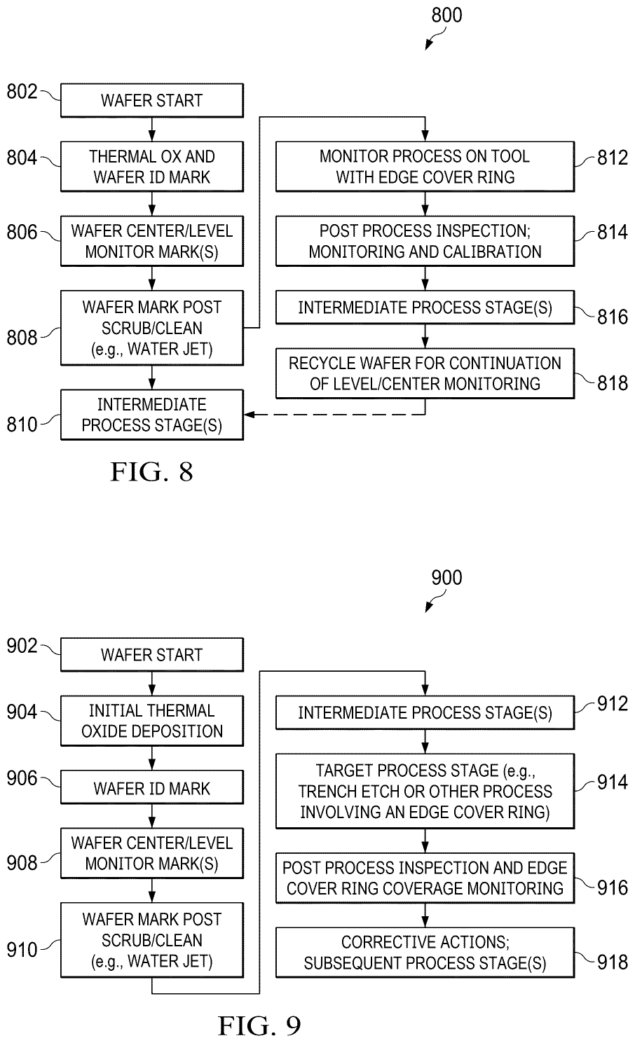

FIG. 8 depicts a calibration flow 800 for characterizing a ring-to-wafer level alignment monitoring system based on fiducial markers according to some examples. In some implementations, short flow monitor wafers, e.g., test wafers, pilot wafers, etc., may be used in the calibration flow 800. A wafer start block 802 commences the calibration flow 800, where suitable wafers are obtained for characterizing and tuning a center/level monitoring system. A protective thermal oxide layer may be formed for facilitating safe handling and transport of the wafers in some arrangements, where the wafers may be laser engraved with unique tracking IDs as previously mentioned (block 804). At block 806, suitable fiducial markers may be laser engraved on the wafers at respective locations along a perimeter of the wafers, which may be spaced from the wafer edge by an appropriate distance (e.g., having an equal distance) depending on the edge cover ring deployments in a fabrication flow. For example, if a processing tool has an edge cover ring having a narrow flange (which causes a narrow annular process exclusion area), the fiducial markers may be placed closer to the wafer edge.

A wafer scrub or clean process (block 808) may be provided for removing debris from the wafer surfaces that may have been caused by the laser marking process. In some arrangements, a water jet scrub process may be used although other cleaning methods may be used in some additional and/or alternative examples. Thereafter, the wafers may be processed through various intermediate stages, as set forth at block 810, until a target process stage including processing wafers covered by a wafer edge cover ring is reached (block 812). Various post-process inspection and monitoring methodologies may be employed, e.g., including human operators, automated expert systems, etc., which may include obtaining correlations between edge cover ring settings, process parameters, expected process exclusion areas, inter-indicia spacings of the fiducial markers, etc. Thereafter, the wafers may be processed through the remaining stages of a flow, which then may be recycled back into the flow, e.g., at some intermediate stage 810, as set forth at blocks 814-818, after adjusting or readjusting equipment settings in accordance with some examples. Depending on repeatability and reliability of level monitoring for various corner cases, a level monitoring system may be characterized as stable with respect to the target process stage. Thereafter, the level monitoring system may be released to production.

FIGS. 9-11 depict flowcharts of example fabrication methods according to some implementations. Method 900 of FIG. 9 may include blocks that are substantially similar to some of the blocks of a calibration flow, e.g., the calibration flow 800 set forth above, except that production wafers may be used for commencing (block 902) the fabrication of IC chips using process stages that may employ suitably characterized level monitoring systems based on fiducial markers according to the examples of the present disclosure. The description of blocks 804-816 may therefore be suitably applied to the acts and functions set forth at blocks 904-916, taking note that laser scribe marking of production wafers at block 908 may include unique product ID markers in addition to tracking markers and fiducial markers. At block 914, a target process stage may include an edge-ring-based process, e.g., trench etch, PECVD, etc. Responsive to post-process inspection and edge ring coverage monitoring (block 916), one or more corrective actions may be executed with respect to the process stage equipment in addition to appropriate product dispositioning, which may include advancing the product wafers to subsequent fabrication stages as previously noted (block 918).

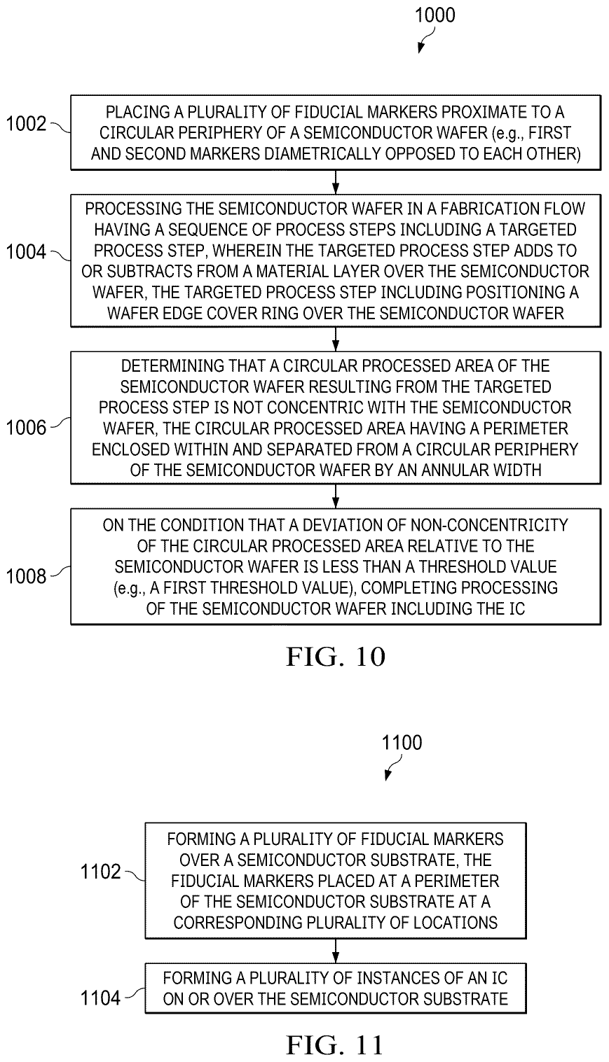

Method 1000 of FIG. 10 may commence with placing a plurality of fiducial markers proximate to a circular periphery of a semiconductor wafer (block 1002). In an example implementation, the fiducial markers may include a first fiducial marker and a second fiducial marker that are placed diametrically opposed to each other while avoiding a flat or a notch of the wafer. At block 1004, the semiconductor wafer is processed in a fabrication flow having a sequence of process steps including a targeted process step, where the targeted process step adds to or subtracts from a material layer over the semiconductor wafer. As described previously, the targeted process step may include positioning a wafer edge cover ring over the semiconductor wafer. After processing the semiconductor wafer at the targeted process step, a monitoring step may involve determining that a circular processed area of the semiconductor wafer resulting from the targeted process step is not concentric with the circular periphery of the semiconductor wafer, where the circular processed area may have a perimeter enclosed within and separated from the circular periphery by an annular width (block 1006). In some arrangements, the determining may be based on measuring a deviation of the annular width from an expected uniform width. Method 1000 may include completing processing of the semiconductor wafer including the IC on the condition that the deviation is less than a first threshold value (block 1008). In some arrangements, an example method may further include adjusting a setting of the edge cover ring responsive to determining that the deviation of the annular width is greater than a second threshold value, which may be greater than the first threshold value.

Method 1100 of FIG. 11 may commence with forming a plurality of fiducial markers over a semiconductor substrate, e.g., a semiconductor wafer (block 1102). In one example, the fiducial markers may comprise laser scribe dot matrix alphanumeric characters, which may be formed at a same step as forming wafer identification and tracking markers. Method 1100 may include forming a plurality of instances of an IC on or over the semiconductor wafer (block 1104). In some examples, the method may include placing an edge cover ring, e.g., partially, over the fiducial markers and performing a plasma process (e.g., deposition, etch, etc.) on the semiconductor substrate. In some examples, the method may include imaging a processed area perimeter in relation to the plurality of the fiducial markers. In some examples, the semiconductor substrate may be located in a process tool in which the plasma process is performed during imaging. In some examples, the semiconductor substrate may be imaged by an inspection tool separate from a process tool in which the plasma process is performed. As previously set forth, some aspects of the foregoing methods may advantageously include suitable product dispositioning and equipment adjustment depending on the inspection of process exclusion areas and edge ring coverage monitoring.

While various examples of the present disclosure have been described above, they have been presented by way of example only and not limitation. Numerous changes to the disclosed examples can be made in accordance with the disclosure herein without departing from the spirit or scope of the disclosure. Thus, the breadth and scope of the present disclosure should not be limited by any of the above described examples. Rather, the scope of the disclosure should be defined in accordance with the claims appended hereto and their equivalents.

One or more examples of the present disclosure may be implemented using different combinations of software, firmware, and/or hardware. Thus, one or more of the techniques shown in the Figures (e.g., flowcharts) may be implemented using code and data stored and executed on one or more electronic devices or nodes (e.g., a workstation, a network element, etc.). Such electronic devices may store and communicate (internally and/or with other electronic devices over a network) code and data using computer-readable media, such as non-transitory computer-readable storage media (e.g., magnetic disks, optical disks, random access memory, read-only memory, flash memory devices, phase-change memory, etc.), transitory computer-readable transmission media (e.g., electrical, optical, acoustical or other form of propagated signals-such as carrier waves, infrared signals, digital signals), etc. In addition, some network elements or workstations, e.g., configured as servers, may typically include a set of one or more processors coupled to one or more other components, such as one or more storage devices (e.g., non-transitory or persistent machine-readable storage media) as well as storage database(s), user input/output devices (e.g., a keyboard, a touch screen, a pointing device, one or more imaging capturing devices and/or a display, etc.), and network connections for effectuating signaling and/or data transmission.

Further, in at least some additional or alternative implementations, the functions/acts described in the blocks may occur out of the order shown in the flowcharts. For example, two blocks shown in succession may in fact be executed substantially concurrently or the blocks may sometimes be executed in the reverse order, depending upon the functionality/acts involved. Moreover, the functionality of a given block of the flowcharts and/or block diagrams may be separated into multiple blocks and/or the functionality of two or more blocks of the flowcharts and/or block diagrams may be at least partially integrated. Also, some blocks in the flowcharts may be optionally omitted. Furthermore, although some of the diagrams include arrows on communication paths to show a primary direction of communication, it is to be understood that communication may occur in the opposite direction relative to the depicted arrows. Finally, other blocks may be added/inserted between the blocks that are illustrated.

The order or sequence of the acts, steps, functions, components or blocks illustrated in any of the flowcharts and/or block diagrams depicted in the drawing Figures of the present disclosure may be modified, altered, replaced, customized or otherwise rearranged within a particular flowchart or block diagram, including deletion or omission of a particular act, step, function, component or block. Moreover, the acts, steps, functions, components or blocks illustrated in a particular flowchart may be inter-mixed or otherwise inter-arranged or rearranged with the acts, steps, functions, components or blocks illustrated in another flowchart in order to effectuate additional variations, modifications and configurations with respect to one or more processes for purposes of practicing the teachings of the present disclosure. Likewise, although various examples have been set forth herein, not all features of a particular example are necessarily limited thereto and/or required therefor.

At least some portions of the foregoing description may include certain directional terminology, such as, “upper”, “lower”, “top”, “bottom”, “left-hand”, “right-hand”, “front side”, “backside”, “vertical”, “horizontal”, etc., which may be used with reference to the orientation of some of the Figures or illustrative elements thereof being described. Because components of some examples can be positioned in a number of different orientations, the directional terminology is used for purposes of illustration only and is in no way limiting. Likewise, references to features referred to as “first”, “second”, etc., are not indicative of any specific order, importance, and the like, and such references may be interchanged, depending on the context, implementation, etc. In addition, terms such as “over”, “under”, “below”, etc., relative to the spatial orientation of two components does not necessarily mean that one component is immediately over the other component, or that one component is immediately under or below the other component. Further, the features and/or components of examples described herein may be combined with each other unless specifically noted otherwise.

Although various implementations have been shown and described in detail, the claims are not limited to any particular implementation or example. None of the above Detailed Description should be read as implying that any particular component, element, step, act, or function is essential such that it must be included in the scope of the claims. Where the phrases such as “at least one of A and B” or phrases of similar import are recited or described, such a phrase should be understood to mean “only A, only B, or both A and B.” Reference to an element in the singular is not intended to mean “one and only one” unless explicitly so stated, but rather “one or more.” In similar fashion, phrases such as “a plurality” or “multiple” may mean “one or more” or “at least one”, depending on the context. All structural and functional equivalents to the elements of the above-described implementations are expressly incorporated herein by reference and are intended to be encompassed by the claims appended below.

What is claimed is:

1. A semiconductor processing tool, comprising:
a wafer stage; and
an imaging system configured to determine a spatial relationship between a processed area of a semiconductor substrate on the wafer stage and a plurality of fiducial markers placed at a corresponding plurality of locations along a perimeter of the semiconductor substrate.

2. The semiconductor processing tool of claim 1, wherein the wafer stage is a wafer stage of a plasma processing tool.

3. The semiconductor processing tool of claim 1, wherein the wafer stage is a wafer stage of an optical inspection tool.

4. The semiconductor processing tool of claim 1, wherein the imaging system is configured to determine a distance of a perimeter of the processed area from a perimeter of the semiconductor substrate at each of the plurality of locations.

5. The semiconductor processing tool of claim 1, wherein the imaging system is configured to determine an offset of a center of the processed area from a center of the semiconductor substrate.

6. The semiconductor processing tool of claim 1, wherein the plurality of fiducial markers are spaced from an edge of the semiconductor substrate by a same distance.

7. The semiconductor processing tool of claim 1, wherein the fiducial markers each include a laser scribe dot matrix having a plurality of dots arranged in rows and columns.

8. A method of manufacturing an integrated circuit (IC), comprising:
forming a plurality of fiducial markers over a semiconductor substrate, the fiducial markers placed at a perimeter of the semiconductor substrate at a corresponding plurality of locations; and
forming a plurality of instances of the IC on or over the semiconductor substrate.

9. The method of claim 8, wherein the fiducial markers are instances of a same marker design.

10. The method of claim 8, wherein the fiducial markers include an alphanumeric character.

11. The method of claim 8, wherein the fiducial markers have a long axis oriented along a radial of the semiconductor substrate.

12. The method of claim 8, wherein the fiducial markers are spaced from an edge of the semiconductor substrate by a same distance.

13. The method of claim 8, further comprising imaging a processed area perimeter in relation to the plurality of fiducial markers.

14. The method of claim 8, further comprising placing an edge cover ring over the fiducial markers and performing a plasma process on the semiconductor substrate.

15. The method of claim 14, wherein the semiconductor substrate is located in a process tool in which the plasma process is performed during the imaging.

16. The method of claim 14, wherein the semiconductor substrate is imaged by an inspection tool separate from a process tool in which the plasma process is performed.

17. The method of claim 8, wherein the fiducial markers are placed on axes of a rectilinear coordinate space that are rotated with respect to a crystal orientation of the semiconductor substrate.

18. A semiconductor wafer, comprising:
a semiconductor substrate;
a plurality of instances of the IC on or over the semiconductor substrate; and
a plurality of fiducial markers over the semiconductor substrate, the fiducial markers placed at a perimeter of the semiconductor substrate at a corresponding plurality of locations.

19. The semiconductor wafer of claim 18, wherein the fiducial markers are instances of a same marker design.

20. The semiconductor wafer of claim 18, wherein the fiducial markers include an alphanumeric character.

21. The semiconductor wafer of claim 18, wherein the fiducial markers have a long axis oriented along a radial of the semiconductor substrate.

22. The semiconductor wafer of claim 18, wherein the fiducial markers are spaced from an edge of the semiconductor substrate by a same distance.

23. The semiconductor wafer of claim 18, wherein the fiducial markers are located on axes of a rectilinear coordinate space that are rotated with respect to a crystal orientation of the semiconductor substrate.
